(19) United States
(12) Patent Application Publication
(10) Pub. No.: US 2015/0095734 A1
(43) Pub. Date: Apr. 2, 2015

(54) DETECTING HIDDEN FAULT USING FAULT DETECTION CIRCUIT

(71) Applicant: EMC Corporation, Hopkinton, MA (US)

(72) Inventors: Shan Chen, Hangzhou (CN); Zhe Wang, Shanghai (CN); Hao Hu, Shanghai (CN); Wei An, Shanghai (CN); Lei Jiang, Shanghai (CN)

(21) Appl. No.: 14/497,985

(22) Filed: Sep. 26, 2014

(30) Foreign Application Priority Data
Sep. 27, 2013 (CN) CN201310453061.9

(51) Int. Cl. G01R 31/3177

(52) U.S. Cl. CPC G01R 31/3177
USPC 714/736

(57) ABSTRACT

Embodiments of the present invention disclose a hidden fault detection circuit and a method of detecting a hidden fault using the hidden fault detection circuit. The hidden fault detection circuit comprises a function module for indicating a working state of an integrated circuit board to which the hidden fault detection circuit belongs; and a hidden fault detection module for detecting a hidden fault existing in the function module according to output of the function module. The hidden fault may be detected and eliminated according to embodiments of the present invention.

### RELATED APPLICATION

This Application claims priority from Chinese Patent Application Serial No. CN201310453061.9 filed on Sep. 27, 2013 entitled “HIDDEN FAULT DETECTION CIRCUIT AND METHOD FOR DETECTING HIDDEN FAULT WITH HIDDEN FAULT DETECTION CIRCUIT,” the content and teachings of which are hereby incorporated by reference in their entirety.

### FIELD

Embodiments of the present invention generally relate to the field of fault detection and of fault detection circuits, and more specifically to a hidden fault detection circuit and detecting a hidden fault using the hidden fault detection circuit.

### BACKGROUND

High availability (hereinafter referred to as “HA”) refers to improvement of availability of the system and application by trying to shorten machine failure duration caused by planned operations such as routine maintenance operations and unplanned operations such as sudden system breakdown. HA system is the one of the most efficient means by which current enterprises prevent failure of a kernel computer system due to a hidden fault.

HA system design requires two fundamental criteria: 1. no single point of failure (no SPOF); and 2. no critical hidden fault. Only when both criteria are met can the system be guaranteed with high availability.

In current HA designs, typically the first criterion, “No SPOF”, is achieved securely in the design process through FMEA (Failure Mode and Effects Analysis). But the second criterion, “No Critical Hidden Fault” is typically not 100% secured. This is illustrated by presenting an insertion signal indication circuit as an example.

FIG. 1 is a view illustrating an insertion signal indication circuit 100 according to the relevant technology. As shown in FIG. 1, the insertion signal indication circuit 100 comprises two ICM boards (also called ICMA and ICMB), which may be inserted into a chassis respectively, i.e., coupled to a midplane. When the ICM board is inserted into the chassis, a signal S1_N may be reduced by grounding a resistor (Ra1) on the board so as to indicate an insertion status of the ICM board. This S1_N may be sensed by a PSU (power supply unit, which may include PSU A and PSU B) and is used as an enable/disable signal for PSU to turn on/off itself. Noticeably, the circuits on ICM A and ICM B are implemented in the same manner.

However, such insertion status indication circuit forms a hidden fault case as illustrated below:

Regarding an active low insertion status indication circuit, if Ra1 is open on one ICM board, since the ICM B is still inserted in the chassis, the shared S1_N keeps low despite the failure of Ra1, that is to say, the fault cannot be reflected normally at an output terminal of a conventional signal of the insertion status indication circuit.

In this case, if ICM B is faulted later for some reasons and must be replaced to fix that issue, since no symptom indicates that ICM A has any occurrence of failure, the service personnel will think that ICM A is OK and there should be no problem to replace ICM B. However, once ICM B is pulled out, signal S1_N will jump high and all PSUs in the chassis will be turned off, thereby causing data unusability/data loss (DU/DL).

### SUMMARY

To this end, embodiments of the present invention provide a hidden fault detection circuit and a method of detecting a hidden fault using the hidden fault detection circuit.

According to one embodiment of the present invention, there is provided a hidden fault detection circuit, comprising a function module for indicating a working state of an integrated circuit board to which the hidden fault detection circuit belongs; and a hidden fault detection module for detecting a hidden fault existing in the function module according to output of the function module.

In a further embodiment, the working state comprises an insertion state of the integrated circuit board to which the hidden fault detection circuit belongs, and an alarm state caused by reduction of input voltage to be detected in the integrated circuit board to which the hidden fault detection circuit belongs.

In a further embodiment, the hidden fault detection circuit further comprises an intermediate node between the function module and the hidden fault detection module, wherein the hidden fault detection module detects the hidden fault existing in the function module according to a signal level of the intermediate node.

In a further embodiment, the hidden fault detection module comprises: a first coupling module coupled in series to the function module; and a hidden fault indication module for indicating the hidden fault existing in the function module according to the signal level of the intermediate node between the first coupling module and the function module.

In a further embodiment, the hidden fault indication module comprises: a first diode which first terminal is coupled to the intermediate node and which second terminal is used to indicate the hidden fault existing in the function module; and a second coupling module which first terminal is coupled to the second terminal of the first diode.

In yet a further embodiment, when the level for indicating the hidden fault existing in the function module is set to be a high level, the first terminal of the first diode is set to be a positive electrode, and the second terminal of the first diode is set to be a negative electrode; when the level for indicating the hidden fault existing in the function module is set to be a low level, the first terminal of the first diode is set to be a negative electrode, and the second terminal of the first diode is set to be a positive electrode.

In yet a further embodiment, the function module comprises: a third coupling module coupled in series to the first coupling module; an isolation module for isolating interference in the working state when the signal level of the intermediate node is a high level or a low level.

In a further embodiment, the first coupling module and the third coupling module have the same resistance value.

In a further embodiment, the isolation module comprises a second diode which first terminal is coupled to the intermediate node and which second terminal is used to indicate the working state.

In yet a further embodiment, when the level for indicating the hidden fault existing in the function module is set to be a high level, the first terminal of the second diode is set to be a negative electrode, and the second terminal of the second diode is set to be a positive electrode; when the level for indicating the hidden fault existing in the function module is set to be a low level, the first terminal of the second diode is set to be a positive electrode, and the second terminal of the second diode is set to be a negative electrode.

In a further embodiment, the hidden fault detection circuit further comprises a general purpose input/output signal line which detects the hidden fault existing in the function module according to the signal level of the intermediate node.

According to aspect further embodiment of the present invention, there is provided a method of detecting a hidden fault by using the hidden fault detection circuit, the hidden fault detection circuit comprising the function module and the hidden fault detection module. The method comprises the following steps: indicating a working state of an integrated circuit board to which the hidden fault detection circuit belongs; and detecting a hidden fault existing in the function module according to output of the function module.

In a further embodiment, the working state comprises an insertion state of the integrated circuit board to which the hidden fault detection circuit belongs, and an alarm state caused by reduction of input voltage to be detected in the integrated circuit board to which the hidden fault detection circuit belongs.

In a further embodiment, the hidden fault detection circuit further comprises an intermediate node between the function module and the hidden fault detection module. The detecting a hidden fault existing in the function module according to output of the function module comprises: the hidden fault detection module detecting the hidden fault existing in the function module according to a signal level of the intermediate node.

In yet a further embodiment, the hidden fault existing in the function module is detected according to a signal level of the intermediate node by using a general purpose input/output signal line included by the hidden fault detection circuit.

### BRIEF DESCRIPTION OF THE DRAWINGS

The above and other objects, features and advantages of embodiments of the present invention will be made more apparent by reading the following detailed description with reference to the figures. In the figures, several embodiments of the present invention will be illustrated in an exemplary and unrestrictive manner, wherein:

FIG. 1 is an exemplary diagram that illustrates an insertion signal indication circuit 100 according to relevant technologies.

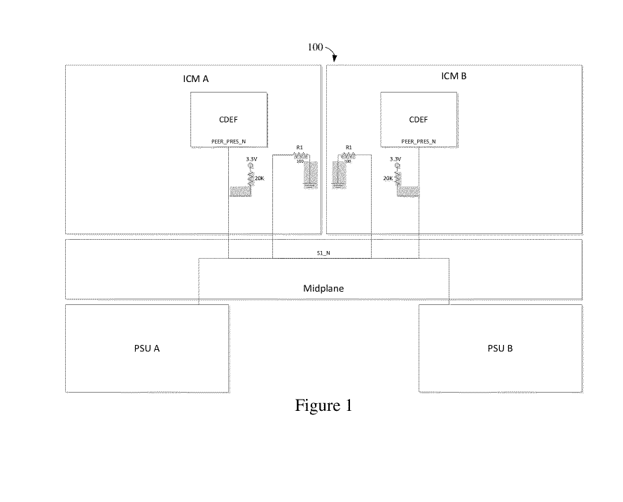

FIG. 2 is an exemplary diagram that illustrates a structural block diagram of a hidden fault detection circuit 200 according to an embodiment of the present invention.

FIG. 3 is an exemplary diagram that illustrates an insertion signal indication circuit 300 using a hidden fault detection circuit according to an embodiment of the present invention.

FIG. 4 is an exemplary diagram that illustrates a circuit 400 for monitoring multiple inputs according to relevant technology.

FIG. 5 is an exemplary diagram that illustrates a circuit 500 for monitoring multiple inputs using a hidden fault detection circuit according to an embodiment of the present invention.

FIG. 6 is an exemplary diagram that illustrates a flow chart of a method of detecting a hidden fault by using the hidden fault detection circuit according to the embodiment of the present invention.

It should be appreciated that the flowcharts and block diagrams in the figures illustrate an apparatus, a method, as well as architecture, functions and operations executable by a computer program product according to the embodiments of the present invention. In this regard, each block in the flowcharts or block diagrams may represent a module, a program segment, or a part of code, which contains one or more executable instructions for performing specified logic functions. It should also be noted that, in some alternative implementations, the functions noted in the block may occur out of the order noted in the figures. For example, two blocks shown consecutively may be performed in parallel substantially or in an inverse order, depending on involved functions. It should also be noted that each block in the block diagrams and/or flow charts and a combination of blocks in block diagrams and/or flow charts may be implemented by a dedicated hardware-based system for executing a prescribed function or operation or may be implemented by a combination of dedicated hardware and computer instructions.

### DETAILED DESCRIPTION

Principles and spirit of the present invention will be described below with reference to several exemplary embodiments illustrated in the figures. It should be appreciated that these embodiments are presented only to enable those skilled in the art to better understand and thereby implement the present disclosure, not to limit the scope of the present disclosure in any manner.

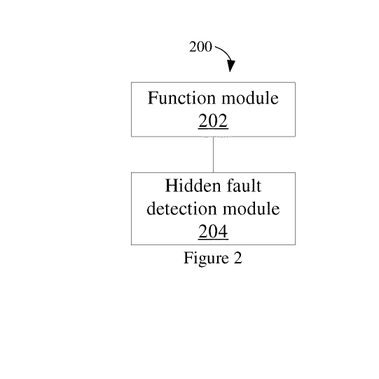

FIG. 2 is an exemplary diagram that illustrates a structural block diagram of a hidden fault detection circuit 200 according to an embodiment of the present invention. As shown in FIG. 2, the hidden fault detection circuit 200 comprises a function module 202 for indicating a working state of an integrated circuit board to which the hidden fault detection circuit 200 belongs, and also includes a hidden fault detection module 204 for detecting a hidden fault in the function module 202 according to output of the function module 202.

In embodiments, the working state comprises an insertion state of the integrated circuit board to which the hidden fault detection circuit 200 belongs, and an alarm state caused by reduction of input voltage to be detected in the integrated circuit board to which the hidden fault detection circuit 200 belongs.

In an embodiment, the hidden fault detection circuit 200 further comprises an intermediate node between the function module 202 and the hidden fault detection module 204, wherein the hidden fault detection module 204 detects the hidden fault existing in the function module 202 in accordance with a signal level associated with the intermediate node.

In one embodiment, the hidden fault detection module 204 comprises: a first coupling module coupled in series to the function module 202; and a hidden fault indication module for indicating the hidden fault existing in the function module 202 in accordance with the signal level associated with the intermediate node between the first coupling module and the function module 202.

In one embodiment, the hidden fault indication module comprises a first diode, wherein a first terminal is coupled to the intermediate node and a second terminal is used to indicate the hidden fault existing in the function module 202; and a second coupling module wherein a first terminal is coupled to the second terminal of the first diode.

In one embodiment, when the level for indicating the hidden fault existing in the function module 202 is set to be high (a high level), the first terminal of the first diode is set to be a positive electrode, and the second terminal of the first diode is set to be a negative electrode; when the level for indicating the hidden fault existing in the function module 202 is set to be low (a low level), the first terminal of the first diode is set to be a negative electrode, and the second terminal of the first diode is set to be a positive electrode.

In one embodiment, the function module 202 comprises: a third coupling module coupled in series to the first coupling module; an isolation module for isolating interference in the working state when the signal level of the intermediate node is a high level or a low level.

In one embodiment, the first coupling module and the third coupling module have the same resistance value.

In one embodiment, the isolation module comprises a second diode, wherein a first terminal is coupled to the intermediate node and a second terminal is used to indicate the working state.

In one embodiment, when the level for indicating the hidden fault existing in the function module 202 is set to be a high level, the first terminal of the second diode is set to be a negative electrode and the second terminal of the second diode is set to be a positive electrode; when the level for indicating the hidden fault existing in the function module 202 is set to be a low level, the first terminal of the second diode is set to be a positive electrode and the second terminal of the second diode is set to be a negative electrode.

In one embodiment, the hidden fault detection circuit further comprises a GPIO (general purpose input/output) signal line which detects the hidden fault existing in the function module according to the signal level of the intermediate node.

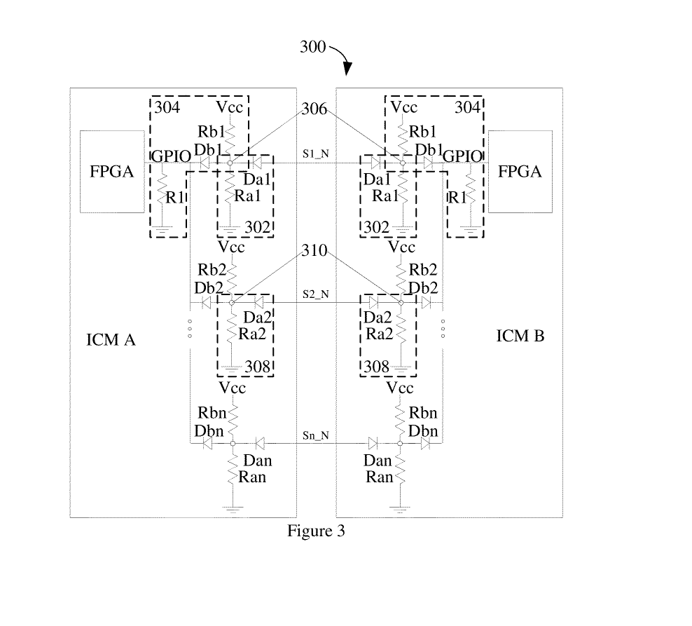

An implementation procedure of the embodiments of the present invention will be described below with reference to FIGS. 3-FIG. 5.

FIG. 3 is an exemplary diagram that illustrates an insertion signal indication circuit 300 using a hidden fault detection circuit according to an embodiment of the present invention. As shown in FIG. 3, the insertion signal indication circuit 300 comprises “n” groups of state indication circuits whose output indication signals are S1_N, S2_N . . . Sn_N, respectively. For purpose of clear description, S1_N, S2_N . . . Sn_N are used below to represent the “n” groups of state indication circuits, respectively. In the following more detailed description, S1_N, S2_N . . . Sn_N may indicate the same content (e.g., all indicate the insertion state) or different content (e.g., S1_N indicates the insertion state whereas S2_N indicates whether the output voltage is in a normal range).

Hereinafter, only S1_N is taken as an example to describe in detail the hidden fault detection circuit 300 shown in FIG. 3. The hidden fault detection circuit 300 comprises a function module 302 (corresponding to the function module 202 in FIG. 2) for outputting the indication signal S1_N (the indication signal S1_N may be used to indicate the working state of the integrated circuit board to which the hidden fault detection circuit 300 belongs) and a hidden fault detection module 304 (corresponding to the hidden fault detection module 204 in FIG. 2) for detecting a hidden fault existing in the function module 302 according to output of the function module 302.

In this embodiment, also the above active low insertion state indication circuit is taken as an example. In normal situations, the function module 302 in the ICM A enables S1_N to have a low level to indicate the insertion state of the ICM A. The low insertion state may be detected by Power Supply Units (PSUs). When the function module 302 in the ICM A is open, for example, the S1_N is still low due to the insertion state in the ICM B. Meanwhile, since the function module 302 in the ICM A is open, the hidden fault detection module 304 will for example output high level at the GPIO signal line to indicate the hidden fault existing in the function module 302. Therefore, when the service personnel attempts to replace the ICM B subsequently, he may acquire the hidden fault existing in the ICM A from for example GPIO signal line of the hidden fault detection module 304 (i.e., is open). If in this case, he will not directly replace the ICM B, thereby avoiding rise of the S1_N caused by direct replacement of ICM B and ensuring all PSUs in the chassis are turned on.

In one embodiment, the hidden fault detection circuit 300 may further include an intermediate node 306 between the function module 302 and the hidden fault detection module 304, wherein the hidden fault detection module 304 may detect the hidden fault existing in the function module 302 in accordance with a signal level of the intermediate node 306. In this embodiment, as for various possible outputs of the function module 302, the hidden fault detection module 304 detects the hidden fault existing in the function module 302 with the signal level of the intermediate node 306 as a criterion, and the signal level for detection may be set to be a high level or a low level according to the situation or demand or need.

In one embodiment, the hidden fault detection module 304 may include a first resistor Rb1 (corresponding to the above first coupling module) coupled in series to the function module 302; and a first diode Db1 and a second resistor R1 (jointly correspond to the above hidden fault indication module) to indicate the hidden fault existing in the function module 306 according to the signal level of the intermediate node 306 between the first resistor Rb1 and the function module 302. In this embodiment, the function module 302 and the first resistor Rb1 are coupled in series between Vcc and the ground, the intermediate node 306 is located between the function module 302 and the first resistor Rb1 and enables the signal level of the intermediate node 306 as a high level to indicate the hidden fault existing in the function module 302 when the function module 302 for example is open.

In one embodiment, the first terminal of the first diode Db1 is coupled to the intermediate node 306 and the second terminal is used to indicate the hidden fault existing in the function module 302; the first terminal of the second resistor R1 is coupled to the second terminal of the first diode Db1. As for the first diode Db1, when the level for indicating the hidden fault existing in the function module 302 is set as a high level (corresponding to the above active low state indication circuit), the first terminal of the first diode Db1 may be set to be a positive electrode, and the second terminal of the first diode Db1 may be set to be a negative electrode, thereby preventing an active low state indication from interfering in an active high hidden fault indication; similarly, when the level for indicating the hidden fault existing in the function module 302 is set as a low level (corresponding to the active high state indication circuit), the first terminal of the first diode Db1 may be set to be a negative electrode, and the second terminal of the first diode Db1 may be set to be a positive electrode, i.e., a direction of the diode is rendered reverse so that the active high state indication is prevented from interfering in the active low hidden fault indication.

In another embodiment, the function module 302 may include a third resistor Ra1 (corresponding to the above third coupling module) coupled in series to the first resistor Rb1; and a second diode Da1 (corresponding to the above isolation module) which first terminal is coupled to the intermediate node 306 and which second terminal is used to indicate the above state to be indicated. As for the second diode Da1, when the level for indicating the hidden fault existing in the function module 302 is set to be a high level (corresponding to the above active low state indication circuit), the first terminal of the second diode Da1 may be set to be a negative electrode, and the second terminal of the second diode Da1 may be set to be a positive electrode, thereby preventing the active high hidden fault indication from interfering in an active low state indication; similarly, when the level for indicating the hidden fault existing in the function module 302 is set to be a low level (corresponding to the active high state indication circuit), the first terminal of the second diode Da1 may be set to be a positive electrode, and the second terminal of the second diode Da1 may be set to be a negative electrode, i.e., a direction of the diode is rendered reverse so that the active low hidden fault indication is prevented from interfering in the active high state indication.

Besides, in the above embodiments, the first resistor Rb1 and the third resistor Ra1 may have the same resistance value.

In one embodiment, the hidden fault detection circuit 300 further comprises a GPIO signal line that detects the hidden fault existing in the function module 302 according to the signal level of the intermediate node 306. In this embodiment, the GPIO signal line may detect the hidden fault existing in a plurality of corresponding function modules according to signal levels of a plurality of intermediate nodes similar to the intermediate node 306. Both S1_N and S2_N are taken as an example below to illustrate the detection of the hidden fault existing in the plurality of function modules by the hidden fault detection circuit 300 as shown in FIG. 3.

The hidden fault detection circuit 300 comprises a first function module 302 used to output the indication signal S1_N (the indication signal S1_N may be for example used to indicate the insertion state of the integrated circuit board to which the hidden fault detection circuit 300 belongs) and a first intermediate node 306 between the first function module 302 and the hidden fault detection module 304. The hidden fault detection circuit 300 further comprises a second function module 308 used to output the indication signal S2_N (the indication signal S2_N may be for example used to indicate whether the output voltage of the integrated circuit board to which the hidden fault detection circuit 300 belongs is in a state within a normal range) and a second intermediate node 310 between the second function module 308 and the hidden fault detection module 304.

In this embodiment, the GPIO signal line may be used to aggregate the hidden fault detected by the first intermediate node 306 and the second intermediate node 310 to indicate the hidden fault existing in the whole of the integrated circuit to which the hidden fault detection circuit 300 belongs. This indication function may be fulfilled by using OR operation diode. In this embodiment, when a serviceman subsequently knows that the hidden fault exists in the whole of the integrated circuit board, he may use a new integrated circuit board to directly replace the integrated circuit board including the hidden fault, regardless of the function module(s) of the integrated circuit board including the hidden fault include the hidden fault.

For illustrative purpose and clarity, embodiments of the present invention further provide an application scenario of the hidden fault detection circuit.

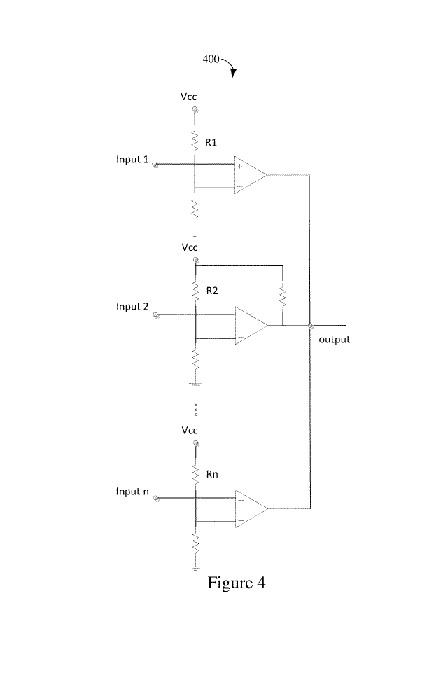

FIG. 4 is an exemplary diagram that illustrates a circuit 400 for monitoring multiple inputs. As shown in FIG. 4, the circuit comprises “n” groups of input monitoring circuits, wherein each group of input monitoring circuit includes an operational amplifier for monitoring one input through an input terminal thereof, input signals thereof are input 1, input 2, . . . input n, respectively. When any one of the “n” inputs falls below a respective threshold, its output will be lowered as a fault alarm signal. However, this circuit for monitoring the multiple inputs includes a hidden fault, namely, any resistor among R1 to Rn coupled to another input terminal of the operational amplifier fails. When any resistor among R1 to Rn fails, since output always aggregates monitoring results of “n” inputs, the failure might not be acquired correctly by the serviceman/engineer.

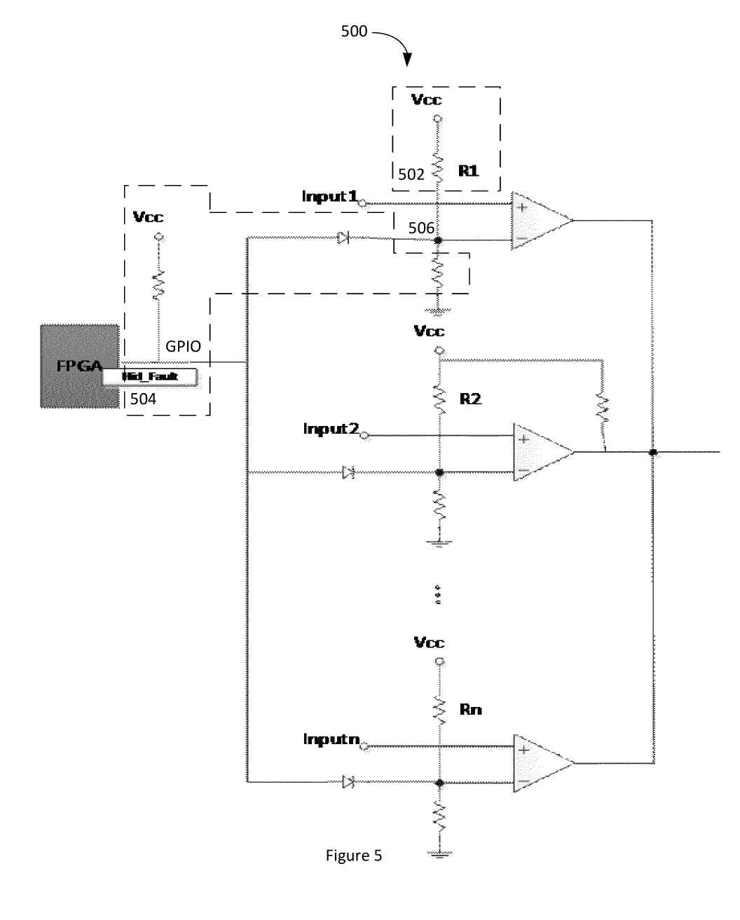

FIG. 5 is an exemplary diagram that illustrates a circuit 500 for monitoring multiple inputs using a hidden fault detection circuit according to an embodiment of the present invention. As shown in FIG. 5, the circuit comprises a function module 502 used to output the indication signal (the indication signal may be used to indicate a state of “n” inputs of the integrated circuit board to which the hidden fault detection circuit 500 belongs) and a hidden fault detection module 504 for detecting a hidden fault existing in the function module 502 according to output of the function module 502.

In this embodiment, also the active low circuit for monitoring multiple inputs described above is taken as an example. In normal situations, the function module 502 makes the output at a high level to indicate a normal input state of the multiple inputs. When the function module 502 for example is open, the hidden fault detection module 504 will for example output a low level at the GPIO signal line to indicate that the function module 502 includes the hidden fault, so that a hidden fault processing program is triggered or activated.

In one embodiment, the hidden fault detection circuit 500 may further comprises an intermediate node 506 between the function module 502 and the hidden fault detection module 504, wherein the hidden fault detection module 504 may detect the hidden fault existing in the function module 502 according to a signal level of the intermediate node 506. In this embodiment, as for various possible outputs of the function module 502, the hidden fault detection module 504 detects the hidden fault existing in the function module 502 with the signal level of the intermediate node 506 as a possible criterion.

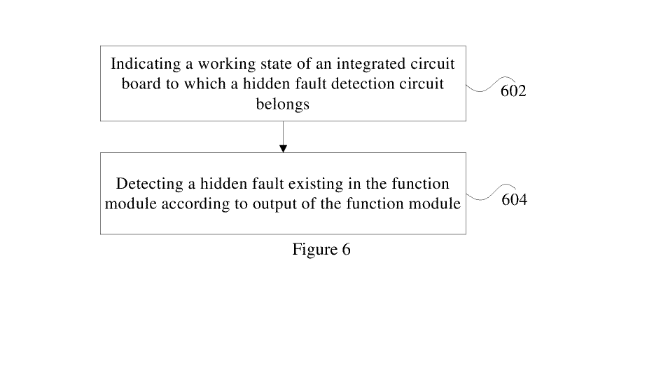

FIG. 6 is a diagram that illustrates an exemplary flow chart of a method for detecting a hidden fault by using the hidden fault detection circuit according to the embodiment of the present invention. The hidden fault detection circuit may take the form of the above circuit comprising the function module and the hidden fault detection module. The method may includes and is not limiting to the following steps:

Step 602: indicating a working state of an integrated circuit board to which the hidden fault detection circuit belongs.

Step 604: detecting a hidden fault existing in the function module according to an output received from the function module.

In all embodiments, the working state comprises an insertion state of the integrated circuit board to which the hidden fault detection circuit belongs, and an alarm state caused by reduction of input voltage to be detected in the integrated circuit board to which the hidden fault detection circuit belongs.

In an embodiment, the hidden fault detection circuit further includes an intermediate node between the function module and the hidden fault detection module, so that the above step 604 may be implemented in a way that the hidden fault detection module detects the hidden fault existing in the function module in accordance with a signal level associated with the intermediate node.

In one embodiment, the hidden fault existing in the function module is detected according to a signal level of the intermediate node by using a general purpose input/output signal line included by the hidden fault detection circuit.

Although the present disclosure has been depicted with reference to several embodiments, it should be understood that the present invention is not limited to the disclosed embodiments. The present disclosure intends to cover various modifications and equivalent arrangements included in the spirit and scope of the appended claims. The scope of the appended claims meets the broadest explanations and covers all such modifications and equivalent structures and functions.

What is claimed is:

1. A hidden fault detection circuit, comprising:
a function module configured for indicating a working state of an integrated circuit board to which the hidden fault detection circuit belongs; and
a hidden fault detection module configured for detecting a hidden fault existing in the function module based on an output of the function module.

2. The hidden fault detection circuit according to claim 1, wherein the working state comprises
an insertion state of the integrated circuit board to which the hidden fault detection circuit belongs, and
an alarm state caused by reduction of input voltage to be detected in the integrated circuit board to which the hidden fault detection circuit belongs.

3. The hidden fault detection circuit according to claim 1, wherein the hidden fault detection circuit further comprises
an intermediate node between the function module and the hidden fault detection module, and wherein the hidden fault detection module detects the hidden fault existing in the function module based on a signal level associated at the intermediate node.

4. The hidden fault detection circuit according to claim 3, wherein the hidden fault detection module comprises:
a first coupling module coupled in series to the function module; and
a hidden fault indication module configured for indicating the hidden fault existing in the function module based on the signal level associated at the intermediate node between the first coupling module and the function module.

5. The hidden fault detection circuit according to claim 4, wherein the hidden fault indication module comprises:
a first diode wherein a first terminal is coupled to the intermediate node and wherein a second terminal is used to indicate the hidden fault existing in the function module;
a second coupling module wherein a first terminal is coupled to the second terminal of the first diode.

6. The hidden fault detection circuit according to claim 5, wherein whilst the level for indicating the hidden fault existing in the function module is set to be a high, the first terminal of the first diode is set to be a positive electrode, and the second terminal of the first diode is set to be a negative electrode;

7. The hidden fault detection circuit according to claim 5, wherein whilst the level for indicating the hidden fault existing in the function module is set to be a low, the first terminal of the first diode is set to be a negative electrode, and the second terminal of the first diode is set to be a positive electrode.

8. The hidden fault detection circuit according to claim 4, wherein the function module comprises:
a third coupling module coupled in series to the first coupling module; and
an isolation module configured for isolating interference in the working state when the signal level of the intermediate node is a high or a low.

9. The hidden fault detection circuit according to claim 8, wherein a resistance value of the first coupling module and a resistance value of the third coupling module are similar or equivalent.

10. The hidden fault detection circuit according to claim 8, wherein the isolation module comprises a second diode wherein a first terminal is coupled to the intermediate node and wherein a second terminal indicates the working state.

11. The hidden fault detection circuit according to claim 10, wherein when the level for indicating the hidden fault existing in the function module is set to be high, the first terminal of the second diode is set to be a negative electrode, and the second terminal of the second diode is set to be a positive electrode.

12. The hidden fault detection circuit according to claim 10, wherein when the level for indicating the hidden fault existing in the function module is set to be low, the first terminal of the second diode is set to be a positive electrode, and the second terminal of the second diode is set to be a negative electrode.

13. The hidden fault detection circuit according to claim 3, further comprises a general purpose input/output signal line configured to detect the hidden fault existing in the function module based on the signal level associated with the intermediate node.

14. A method of detecting a hidden fault by a hidden fault detection circuit, the hidden fault detection circuit comprising a function module and a hidden fault detection module, the method comprising:
indicating a working state of an integrated circuit board to which the hidden fault detection circuit belongs; and
detecting a hidden fault existing in the function module based on an output of the function module.

15. The method of detecting a hidden fault according to claim 14, wherein the working state comprises an insertion state of the integrated circuit board to which the hidden fault detection circuit belongs, and an alarm state caused by reduction of input voltage to be detected in the integrated circuit board to which the hidden fault detection circuit belongs.

16. The method of detecting a hidden fault according to claim 14, wherein the hidden fault detection circuit further comprises an intermediate node between the function module and the hidden fault detection module, configured for
detecting the hidden fault existing in the function module based on the output of the function module further comprising:
detecting the hidden fault existing in the function module based on a signal level associated with the intermediate node.

17. The method of detecting a hidden fault according to claim 16, wherein the hidden fault existing in the function module is detected based on the signal level of associated with the intermediate node using a general purpose input/output signal line included in the hidden fault detection circuit.
